(19) United States
(12) Patent Application Publication
(10) Pub. No.: US 2026/0150526 A1
(43) Pub. Date: May 28, 2026

(54) DISPLAY PANEL, FABRICATION METHOD AND DISPLAY DEVICE

(71) Applicant: Shanghai Tianma Micro-electronics Co., Ltd., Shanghai (CN)

(72) Inventor: Liangwei LIN, Shanghai (CN)

(21) Appl. No.: 19/236,341

(22) Filed: Jun. 12, 2025

(30) Foreign Application Priority Data
Nov. 27, 2024 (CN) 202411721241.5

(51) Int. Cl. H10K 59/124; H10D 86/01; H10D 86/40; H10D 86/60; H10K 59/12

(52) U.S. Cl. CPC H10K 59/124; H10D 86/0221; H10D 86/423; H10D 86/431; H10D 86/60; H10K 59/1201

(57) ABSTRACT

A display panel, a method for fabricating a display panel and a display device are provided. The display panel includes a substrate; and a first active layer, a first gate metal layer, a second active layer, a second gate metal layer, a first insulation layer and a second insulation layer disposed on one side of the substrate. The first insulation layer is located between the first active layer and the first gate metal layer; the second insulation layer is located between the second active layer and the second gate metal layer; the first insulation layer is made of a first type of insulation material; the second insulation layer is made of a second type of insulation material; and an oxygen content of the first type of insulation material is less than an oxygen content of the second type of insulation material.

### CROSS-REFERENCE TO RELATED APPLICATION

This application claims the priority of Chinese Patent Application No. 202411721241.5, filed on Nov. 27, 2024, the content of which is incorporated by reference in its entirety.

### TECHNICAL FIELD

The present disclosure generally relates to the field of display technologies and, more particularly, relates to a display panel, a fabrication method of a display panel and a display device.

### BACKGROUND

Thin-film transistor (TFT) is a key component in display panels, used to control the lighting state of each pixel. It is widely used in display devices such as organic light-emitting diodes (OLED) because of its high mobility, large current switching ratio, good device uniformity, good flexibility and thinness. TFT is mainly composed of semiconductor materials and has three electrodes: source, gate and drain. When a voltage is applied to the gate, the TFT is turned on, allowing current to pass through the source and drain, thereby lighting up the corresponding pixel.

However, there is usually a concentration difference in the source(s) and the drain (d) of the TFT. This difference in hydrogen concentration leads to the formation of sub-channels in the active region of the TFT, which allows electrons or holes to be transmitted through the sub-channels, thereby causing the threshold voltage of the TFT to shift, the on-current to decrease, and affecting the transmission characteristics of the TFT device. The present disclosed display panels and fabrication method are direct to solve such a problem and other problems in the arts.

### SUMMARY

One aspect of the present disclosure provides a display panel. The display panel includes a substrate; and a first active layer, a first gate metal layer, a second active layer, a second gate metal layer, a first insulation layer and a second insulation layer disposed on one side of the substrate. The first insulation layer is located between the first active layer and the first gate metal layer; the second insulation layer is located between the second active layer and the second gate metal layer; the first insulation layer is made of a first type of insulation material; the second insulation layer is made of a second type of insulation material; and an oxygen content of the first type of insulation material is less than an oxygen content of the second type of insulation material.

Another aspect of the present disclosure provides a method for forming a display panel. The method includes providing a substrate; and forming a first active layer, a first gate metal layer, a second active layer, a second gate metal layer, a first insulation layer and a second insulation layer on one side of the substrate. The first insulation layer is located between the first active layer and the first gate metal layer; the second insulation layer is located between the second active layer and the second gate metal layer; the first insulation layer is made of a first type of insulation material; the second insulation layer is made of a second type of insulation material; and an oxygen content of the first type of insulation material is less than an oxygen content of the second type of insulation material.

Another aspect of the present disclosure includes a display device. The display device includes a display panel. The display panel includes a substrate; and a first active layer, a first gate metal layer, a second active layer, a second gate metal layer, a first insulation layer and a second insulation layer disposed on one side of the substrate. The first insulation layer is located between the first active layer and the first gate metal layer; the second insulation layer is located between the second active layer and the second gate metal layer; the first insulation layer is made of a first type of insulation material; the second insulation layer is made of a second type of insulation material; and an oxygen content of the first type of insulation material is less than an oxygen content of the second type of insulation material.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates a cross-sectional view of a TFT;

FIG. 2 illustrates a partial cross-sectional view of an exemplary display panel according to various embodiments of the present disclosure;

FIG. 3 illustrates a top view of an exemplary display panel according to various embodiments of the present disclosure;

FIG. 4 illustrates a circuit diagram of an exemplary pixel driving circuit according to various embodiments of the present disclosure;

FIG. 5 illustrates a partial cross-sectional view of another exemplary display panel according to various embodiments of the present disclosure;

FIG. 6 illustrates a partial cross-sectional view of another exemplary display panel according to various embodiments of the present disclosure;

FIG. 7 illustrates a partial cross-sectional view of another exemplary display panel according to various embodiments of the present disclosure;

FIG. 8 illustrates a partial cross-sectional view of another exemplary display panel according to various embodiments of the present disclosure;

FIG. 9 illustrates a partial cross-sectional view of another exemplary display panel according to various embodiments of the present disclosure;

FIG. 10 illustrates a partial cross-sectional view of another exemplary display panel according to various embodiments of the present disclosure;

FIG. 11 illustrates a flow chart of an exemplary fabrication method of the display panel according to various embodiments of the present disclosure; and

FIG. 12 illustrates an exemplary display device according to various embodiments of the present disclosure.

### DETAILED DESCRIPTION

To more clearly understand the above-mentioned purpose, features and advantages of the embodiments of the present disclosure, the scheme of the embodiments of the present disclosure will be further described below. It should be noted that, in the absence of conflict, the embodiments of the present disclosure and the features in the embodiments can be combined with each other.

In the following description, many specific details are explained to facilitate a full understanding of the embodiments of the present disclosure, but the embodiments of the present disclosure can also be implemented in other ways different from those described herein. Obviously, the embodiments in the specification are only part of the embodiments of the present disclosure, not all of them.

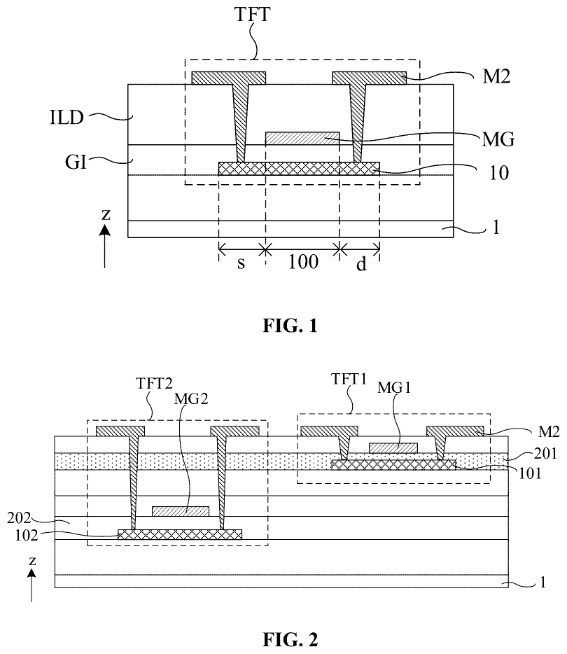

FIG. 1 illustrates a TFT. As shown in FIG. 1, the TFT is mainly composed of an active layer 10 composed of a semiconductor, a gate metal layer MG and a source-drain metal layer M2. In a direction z perpendicular to the plane where the substrate 1 is located, the area where the active layer 10 overlaps with the gate metal layer MG is the active area 100 of the TFT. In the energy band structure of the semiconductor, the bandgap is small, and the electrons or holes in the active area 100 can jump from the valence band to the conduction band under the action of the electric field applied by the gate metal layer MG, thereby reaching the source s and drain d of the conductive TFT.

The display panel further includes multiple insulation layers between the active layer 10, the gate metal layer MG and the source-drain metal layer M2. As shown in FIG. 1, a gate insulation layer (GI) is included between the active layer 10 and the gate metal layer MG, and an interlayer dielectric layer (ILD) is included between the source-drain metal layer M2 and the gate metal layer MG and the active layer 10. The gate insulation layer GI and the interlayer dielectric layer ILD are used to isolate the semiconductor layer from the metal layer, and are also used to reduce the leakage current generated between the source and the drain when the TFT is at the off-state.

The material of the gate insulation layer GI is usually silicon oxide or silicon nitride, and silicon oxide and silicon nitride are usually made from silane. During the preparation process, free hydrogen atoms are generated in the material. These free hydrogen atoms can be used as constant oxidized positive charges to form weak-OH bonds at the interface between the active layer 10 and the gate insulation layer GI, or diffuse to the active layer 10 as shallow negative charges and combine with the semiconductor material.

At the same time, under the action of positive bias temperature stress (PBTS), hydrogen atoms in the gate insulation layer GI follow the electric field formed by the gate voltage to move toward the active layer 10, and the hydrogen atoms near the source s and drain d of the active layer 10 have a higher concentration than the hydrogen atoms in the active region 100. This difference in hydrogen concentration leads to the formation of a sub-channel in the active region 100, which allows electrons or holes to be transmitted through the sub-channel, thereby causing the threshold voltage of the TFT to shift, the on-current to decrease, and the transmission characteristics of the TFT device to be affected.

The present disclosure provides a display panel, a fabrication method of a display panel and display device. FIG. 2 illustrates an exemplary display panel according to various embodiments of the present disclosure.

As shown in FIG. 2, the display panel may include a substrate 1, a first active layer 101, a first gate metal layer MG1, a second active layer 102, a second gate metal layer MG2, a first insulation layer 201, and a second insulation layer 202 located on one side of the substrate 1. The first insulation layer 201 may be located between the first active layer 101 and the first gate metal layer MG1, and the second insulation layer 202 may be located between the second active layer 102 and the second gate metal layer MG2.

The display panel shown in FIG. 2 may include two TFT devices (a first transistor TFT1 and a second transistor TFT2). The first transistor TFT1 may be composed of the first active layer 101 and the first gate metal layer MG1, and the second transistor TFT2 may be composed of the second active layer 102 and the second gate metal layer MG2.

The first insulation layer 201 may be made of a first type of insulation material, and the second insulating layer 202 may be made of a second type of insulation material. The oxygen content of the first type of insulation material may be less than the oxygen content of the second type of insulation material.

The first insulation layer 201 and the second insulation layer 202 may be both gate insulation layers between the gate metal layer and the active layer. The oxygen content of the first insulation layer 201 may be lower. When the oxygen content in the insulation layer is reduced, the pores and defects in the insulation layer may be reduced, thereby improving the compactness of the film layer; at the same time, reducing the oxygen content may optimize the lattice structure composed of atoms of the insulation layer material, making the bonding between atoms of the insulation layer material more uniform and tight, further improving the compactness of the film layer.

When the compactness of the insulation layer is improved, it may be possible to prevent free hydrogen atoms from shuttling in the first insulation layer 201, thereby preventing free hydrogen atoms from contacting the first active layer 101, and avoiding the threshold voltage offset and reduced on-current of the TFT device, thereby improving the stability of the TFT device.

In addition, reducing the oxygen content in the insulation layer may also avoid the introduction of interface states and constant charges, and further avoid the problems caused by free hydrogen atoms. Specifically, reducing the oxygen content may reduce the chance of hydrogen atoms combining with oxygen atoms, thereby reducing the formation of positive ions (i.e., constant charges); and reducing the oxygen content may also reduce the dangling bonds in the interface between the insulation layer and the active layer. The dangling bonds may be the main binding sites of hydrogen atoms. Reducing the dangling bonds may reduce the bonding opportunities of hydrogen atoms, thereby reducing the formation of interface states.

In a fabrication process of TFT, the problem of over-etching also occurs. Over-etching usually etches away the active layer under the gate insulation layer. After the vias overlap the electrodes of the source and drain metal layers, the contact resistance will increase sharply, and finally the turn-on current of the TFT in the over-etched area will deteriorate. In the present disclosure, reducing the oxygen content may improve the uniformity of the insulation layer, reduce the fluctuation of thickness and composition, and avoid the problem of over-etching of the film layer in subsequent processes.

The display panel provided by the embodiments of the present disclosure may disposed a more dense insulation layer with less oxygen content between the active layer and the gate metal layer of the TFT, such that the insulation layer may have both insulation properties and hydrogen blocking ability, avoiding the threshold voltage shift and conduction current reduction of the TFT device caused by the contact between the free hydrogen atoms and the active layer, thereby improving the stability of the TFT device and avoiding over-etching of the TFT.

In the embodiment shown in FIG. 2, the first gate metal layer MG1 and the second gate metal layer MG2 may be respectively located on the side of the first active layer 101 and the second active layer 102 away from the substrate 1. In other embodiments, the first gate metal layer MG1 and the second gate metal layer MG2 may also be located on the side of the first active layer 101 and the second active layer 102 adjacent to the substrate 1, that is, a back-gated structure. The above embodiments of the present disclosure may also be applied to TFTs with back-gated structures, and are also within the scope of protection of the present disclosure.

The material of the gate insulation layer may be silicon nitride, but silicon nitride will produce ammonia during the preparation process, bringing more free hydrogen atoms. In view of this, in some embodiments of the present disclosure, the second type of insulation material may include silicon oxide. The use of silicon oxide may reduce the content of free hydrogen atoms in the insulation layer as much as possible without reducing the oxygen content of the insulation layer.

In other embodiments of the present disclosure, in addition to being the material of the second insulating layer 202, the second type of insulation material may also be used as the material of other film layers in contact with the first insulation layer 201. At this time, the second type of insulation material may be silicon oxide to cooperate with the first insulation layer 201 with a lower oxygen content to reduce the content of free hydrogen atoms in the insulation layer, thereby improving the stability of the TFT device.

The display panel in the above embodiments of the present disclosure may be a low-temperature polycrystalline oxide (LTPO) display panel. LTPO technology is a display panel technology that combines low temperature polysilicon (LTPS) and oxide semiconductors (such as indium gallium zinc oxide, IGZO), which may combine the advantages of the two materials to achieve higher energy efficiency and better display performance. Among them, LTPS transistors may have the advantage of strong driving capability, and IGZO transistors may have the advantage of low leakage current, the pixel driving circuit of the LTPO may achieve very low leakage current and very high refresh rates at the same time. At the same time, because the pixel driving circuit of LTPO may combine the good electron mobility of LTPS transistors and the low leakage current characteristics of IGZO transistors, it may reduce the power consumption of the display panel without affecting the display effect. While ensuring high-quality display effects, it may significantly improve the endurance of the display device.

In some embodiments, as shown in FIG. 2, the first active layer 101 may be an oxide semiconductor layer, and the second active layer 102 may be a polysilicon semiconductor layer. In a more specific embodiment, the first active layer 101 is an indium gallium zinc oxide semiconductor. That is, the first transistor TFT1 is an IGZO transistor, and the second transistor TFT2 is an LTPS transistor.

Since the first active layer 101 is an oxide semiconductor layer, there may be many oxygen vacancies inside it, which may be more susceptible to the influence of free hydrogen ions. Therefore, it may be necessary to set a denser insulation layer (i.e., the first insulation layer 201 with a lower oxygen content) between the first active layer 101 and the first gate metal layer MG1.

In a specific embodiment, such as the embodiment shown in FIG. 2, since the manufacturing cost of a dense insulation layer with a low oxygen content may be high, in the above LTPO display panel, only the gate insulation layer of the IGZO transistor (i.e., the first insulation layer 201 of the first transistor TFT1) may be set as a dense insulation layer with a lower oxygen content, and the gate insulation layer of the LTPS transistor (i.e., the second insulation layer 202 of the second transistor TFT2) may be a more conventional insulation layer composed of the above second type of insulation material. In another specific embodiment, without considering the production cost, to achieve a better display effect, the gate insulation layer of some LTPS transistors may also be set as an insulation layer composed of the above first type of insulation material.

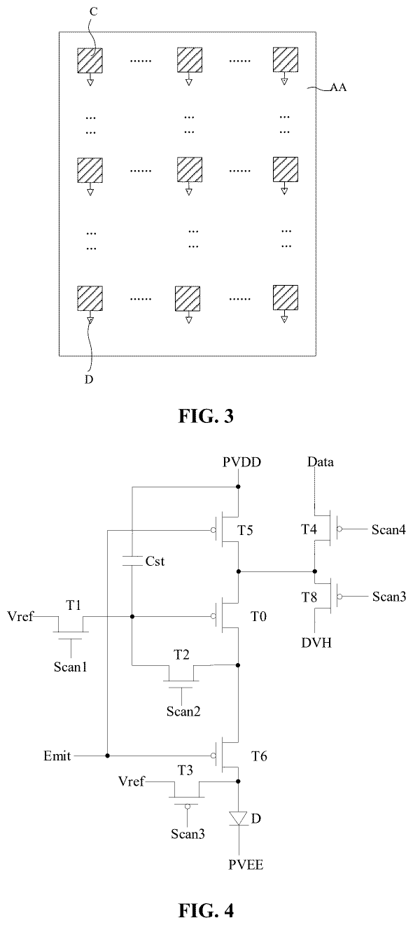

In one embodiment, as shown in FIG. 3, the display panel may include a plurality of pixel driving circuits C and light-emitting elements D arranged in the display area AA. The light-emitting element D may be electrically connected to the pixel driving circuit C, and the pixel driving circuit C may drive the light-emitting element D to emit light according to the driving signal.

As shown in FIG. 4, the pixel driving circuit C may include a driving transistor T0, a gate reset transistor T1, a threshold compensation transistor T2, an anode reset transistor T3, a data writing transistor T4, a first light-emitting control transistor T5, a second light-emitting control transistor T6, a bias transistor T8, and a storage capacitor Cst.

The gate of the gate reset transistor T1 may be electrically connected to the first scanning signal line Scan1, the first electrode of the gate reset transistor T1 may be electrically connected to the reset signal line Vref and may be configured to receive the reset signal, and the second electrode of the gate reset transistor T1 may be electrically connected to the gate of the driving transistor T0. The gate reset transistor T1 may be configured to provide a reset signal to the gate of the driving transistor T0 when it is turned on.

The gate of the threshold compensation transistor T2 may be electrically connected to the second scan signal line Scan2, the first electrode of the threshold compensation transistor T2 may be electrically connected to the second electrode of the driving transistor T0, and the second electrode of the gate reset transistor T1 may be electrically connected to the gate of the driving transistor T0. The threshold compensation transistor T2 may be configured to provide the threshold compensation for the gate of the driving transistor T0 when it is turned on.

The gate of the anode reset transistor T3 may be electrically connected to the third scan signal line Scan3, the first electrode of the anode reset transistor T3 may be electrically connected to the reset signal line Vref and may receive a reset signal, and the second electrode of the anode reset transistor T3 may be electrically connected to the anode of the light-emitting element D. The anode reset transistor T3 may be configured to provide a reset signal to the anode of the light-emitting element D when it is turned on. It should be noted that in other embodiments, the anode reset transistor T3 and the gate reset transistor T1 may be connected to different reset signal lines to receive different reset voltage signals.

The gate of the data writing transistor T4 may be electrically connected to the fourth scan signal line Scan4, the first electrode of the data writing transistor T4 may be electrically connected to the data line Data and may receive a data signal, and the second electrode of the data writing transistor T4 may be electrically connected to the first electrode of the driving transistor T0. The data writing transistor T4 may be configured to provide the data signal to the first electrode of the driving transistor T0 when it is turned on.

The gate of the first light-emitting control transistor T5 may be electrically connected to the light-emitting control signal line Emit, the first electrode of the first light-emitting control transistor T5 may be electrically connected to the power signal line PVDD and may receive the power signal, and the second electrode of the first light-emitting control transistor T5 may be electrically connected to the first electrode of the driving transistor T0. The first light-emitting control transistor T5 may be used to provide the power signal to the first electrode of the driving transistor T0 when it is turned on. The driving transistor T0 may be used to provide a driving signal to the anode of the light-emitting element D according to the above power signal and the data signal.

The gate of the second light-emitting control transistor T6 may be electrically connected to the light-emitting control signal line Emit, the first electrode of the second light-emitting control transistor T6 may be electrically connected to the second electrode of the driving transistor T0, and the second electrode of the second light-emitting control transistor T6 may be electrically connected to the anode of the light-emitting element D. The second light-emitting control transistor T6 may be configured to provide a driving signal to the anode of the light-emitting element D when it is turned on.

The gate of the bias transistor T8 may be electrically connected to the third scan signal line Scan3, the first electrode of the bias transistor T8 may be electrically connected to the bias signal line DVH and may receive the bias signal, and the second electrode of the bias transistor T8 may be electrically connected to the first electrode of the driving transistor T0 and the second electrode of the data writing transistor T4. The bias transistor T8 may be configured to provide the bias signal to the first electrode of the driving transistor T0 when it is turned on.

The storage capacitor Cst may be electrically connected between the power signal line PVDD and the gate of the driving transistor T0.

In one embodiment, the pixel driving circuit C shown in FIG. 4 may be an LTPO pixel driving circuit. The driving transistor T0, the anode reset transistor T3, the data writing transistor T4, the first light-emitting control transistor T5, the second light-emitting control transistor T6, and the bias transistor T8 may all be the above-mentioned LTPS transistors. The gate reset transistor T1 and the threshold compensation transistor T2 may all be the above-mentioned IGZO transistors.

In some embodiments, the above-mentioned first type of insulation material may be formed by an atomic layer deposition (ALD) or a high density plasma chemical vapor deposition (HDPCVD) method.

The ALD method is a thin-film deposition technology that deposits atomic-level thin films layer-by-layer through self-limiting surface chemical reactions, may have a good conformality, may accurately control the film thickness, and may obtain high-quality film properties.

In a specific implementation, the process of forming the insulation layer by the ALD method may include: 1. substrate preparation: a substrate including the lower structure may be placed into the reaction chamber, which may usually be carried out in vacuum or inert gas; 2. precursor introduction: a first precursor gas may be introduced into the reaction chamber and absorbed to the surface of the substrate by physical adsorption or chemical adsorption to form a monolayer. The precursor gas may be introduced in excess to ensure that the surface is completely saturated, and then the excess gas may be removed by exhaustion or purge; 3. chemical reaction: a second precursor gas may be introduced to react chemically with the first precursor to generate the required insulation material. The reaction may only occur on the surface adsorbed by the first precursor; 4. removal of excess precursor: excess second precursor gas may be removed by exhaustion or purge; and 5. repeating the cycles: the above steps may be repeated, and a thin film may be deposited each time when a cycle is completed. By controlling the number of cycles, the thickness of the generated insulation layer may be precisely controlled.

The ALD method may deposit only one atomic layer or molecular layer in each cycle by the layer-by-layer deposition. This self-limiting reaction mechanism ensures that each deposition may only react on the exposed surface, thereby avoiding unnecessary oxidation reactions. Moreover, the ALD method is usually carried out in a high vacuum or low pressure environment. In each deposition, the precursor gas is introduced in excess to ensure that the surface is completely saturated; in the process of introducing and removing the precursor gas, an inert gas (such as nitrogen or argon) is usually used for purging, thereby reducing the introduction of impurities such as oxygen. Furthermore, the insulation material and insulation layer generated by the ALD process may have a low oxygen content, which may provide a denser insulation layer, such that the insulation layer may have both insulation properties and hydrogen barrier capabilities, avoiding the threshold voltage shift and conduction current reduction of the TFT device caused by the contact between free hydrogen atoms and the active layer, thereby improving the stability of the TFT device.

In addition, since the ALD method deposits only one atomic layer or molecular layer in each cycle through layer-by-layer deposition, it may ensure the uniformity of the final film layer, reduce the fluctuation of thickness and composition, and thus avoid the problem of over-etching of the film layer in subsequent processes.

The HDPCVD method is another thin-film deposition technology that uses high-density plasma to promote chemical reactions to deposit high-quality thin films on a substrate.

In a specific implementation, the process for forming an insulation layer by the HDPCVD method may include: 1. plasma generation: the high-density plasma may be generated by methods such as inductive coupling or capacitive coupling. The plasma may have high ion density and low electron temperature and may provide an efficient chemical reaction environment; 2. chemical reaction: the reaction precursor gas may be introduced into the reaction chamber, and the active particles (such as ions, free radicals and electrons) in the high density plasma may react with the precursor gas to form the required insulation material; and 3.controlling the parameters: the density and activity of the plasma may be adjusted by controlling the plasma power, the reaction conditions may be optimized by controlling the pressure of the reaction chamber, and the crystallinity and stress of the film may be affected by controlling the substrate temperature.

The active particles in the high-density plasma may efficiently promote chemical reactions and reduce unnecessary oxidation reactions. The HDPCVD process may be carried out in a high vacuum or low pressure environment, which may remove oxygen and other impurity gases in the reaction chamber. When introducing the precursor gas, an inert gas (such as nitrogen or argon) may usually be used for purging, thereby reducing the introduction of impurities such as oxygen. Furthermore, the insulation material and insulation layer generated by the HDPCVD process may have a lower oxygen content, which may provide a denser insulation layer, such that the insulation layer may have both insulation properties and hydrogen blocking ability, avoiding the threshold voltage shift and reduced on-current of the TFT device caused by the contact between free hydrogen atoms and the active layer, thereby improving the stability of the TFT device.

In addition, since plasma activation may promote uniform chemical reactions, the uniformity of the film layer finally generated may be guaranteed, the fluctuation of thickness and composition may be reduced, and the problem of over-etching of the film layer in subsequent processes may be avoided.

In the above-mentioned embodiment of generating the first type of insulation material by atomic layer deposition or high-density plasma chemical vapor deposition, the first type of insulation material may include silicon oxide or silicon nitride to reduce material costs, and at the same time, it may also ensure that the first type of insulation material may have a lower oxygen content. The above-mentioned second type of insulation material may include silicon oxide or silicon nitride generated by a conventional chemical vapor deposition (CVD) process. In one embodiment, the second type of insulation material is silicon oxide.

In some embodiments, the first type of insulation material may include aluminum oxide (Al2O3) or hafnium oxide (HfO2).

First, silicon nitride may produce ammonia during the preparation process, bringing more free hydrogen atoms, so compared with silicon nitride, silicon oxide may have better hydrogen resistance. Secondly, compared with silicon oxide, aluminum oxide and hafnium oxide may have lower oxygen atom density (in aluminum oxide, each aluminum atom is combined with three oxygen atoms, while in silicon oxide, each silicon atom is combined with two oxygen atoms; although the chemical formulas of hafnium oxide and silicon oxide both indicate that each metal atom is combined with two oxygen atoms, the atomic weight of hafnium atoms (178.49) is much greater than that of silicon atoms (28.09)). Therefore, on the basis of the same thickness, the oxygen content of the insulation layer composed of aluminum oxide or hafnium oxide is lower than that of the insulation layer composed of silicon oxide, which may provide a denser insulation layer. Accordingly, the insulation layer may have both insulation properties and hydrogen resistance, avoiding the problem of threshold voltage shift and reduced on-current of TFT devices caused by contact between free hydrogen atoms and the active layer, thereby improving the stability of TFT devices.

In specific implementation, when the first type of insulation material is aluminum oxide or hafnium oxide, the preparation method of the corresponding insulation layer can adopt the above-mentioned atomic layer deposition method or high-density plasma chemical vapor deposition method, or may adopt the conventional chemical vapor deposition method or other related technologies to generate the insulation layer.

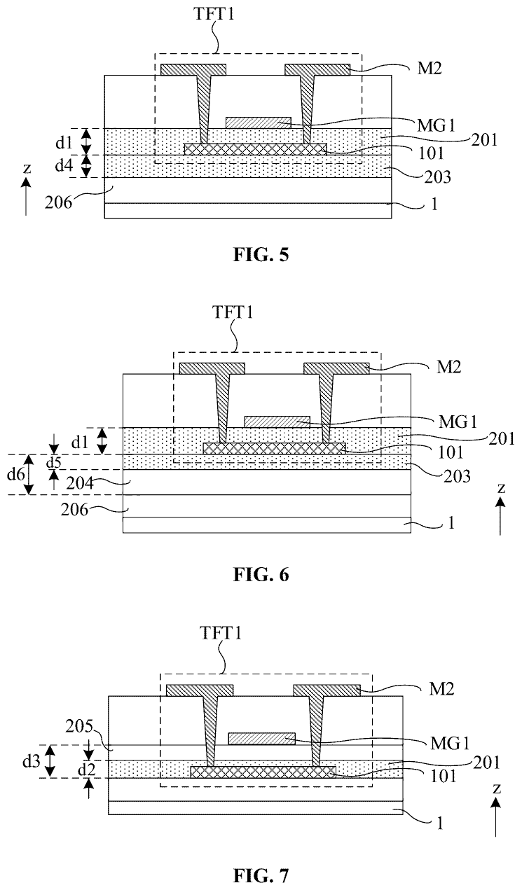

In some embodiments, as shown in FIG. 5, the display panel may also include a third insulation layer 203. The third insulation layer 203 may be located on the side of the first active layer 101 away from the first gate metal layer MG1, and the third insulation layer may be also composed of the first type of insulation material. The third insulation layer 203 and the first insulation layer 201 may jointly wrap the first active layer 101, further preventing the free hydrogen atoms in the insulation layer from contacting the first active layer 101, and improving the stability of the TFT device.

In one embodiment, the third insulating layer 203 may be exactly the same as the material and preparation process of the first insulation layer 201 to ensure process consistency. In other embodiments, it may also be different within the range of the first type of insulation material provided in the above embodiment.

In some embodiments, as shown in FIG. 5, the display panel may further include a sixth insulation layer 206, which may be located on the side of the third insulation layer 203 away from the first active layer 101, and only the third insulation layer 203 may be included between the first active layer 101 and the sixth insulation layer 206. The sixth insulation layer 206 may include silicon nitride. Specifically, the sixth insulation layer 206 may be an interlayer dielectric layer ILD, which may be usually composed of silicon nitride material and contain a large number of free hydrogen atoms. At this time, the third insulation layer 203 may be provided to further prevent the free hydrogen atoms in the insulation layer from contacting the first active layer 101, thereby improving the stability of the TFT device.

It can be understood that FIG. 5 does not show the entire cross-sectional structure of the display panel during specific implementation. On the basis of the embodiment shown in FIG. 5, the display panel provided in the embodiment of the present disclosure may also include other layers, and are not be described here.

In some embodiments, as shown in FIG. 6, the display panel may further include a fourth insulation layer 204, which may be located on the side of the third insulation layer 203 away from the first active layer 101. The fourth insulation layer 204 may be made of the second type of insulation material. Specifically, when the display panel includes the sixth insulation layer 206, the fourth insulation layer 204 may be located between the third insulation layer 203 and the sixth insulation layer 206.

To generate a denser insulation layer, compared with the second type of insulation material, the insulation layer made of the first type of insulation material may require a larger production cost, at the same time, the insulation layer in the display panel may need to have a certain thickness to ensure that the insulation layer to have a certain breakdown voltage, control leakage current, reduce the influence of interface states and fixed charges, and improve the mechanical strength and reliability of the device.

In view of this, to reduce the manufacturing cost while ensuring the thickness of the insulation layer, the above embodiment of the present disclosure may set the fourth insulation layer 204 made of the second type of insulation material under the third insulation layer 203 to reduce the amount of the first type of insulation material. At the same time, the third insulation layer 203 may be located between the fourth insulation layer 204 and the first active layer 101, ensuring the insulation performance and hydrogen barrier capability of the stacked insulation structure composed of the third insulation layer 203 and the fourth insulation layer 204, avoiding the threshold voltage shift and the reduction of the on-current of the TFT device caused by the contact between the free hydrogen atoms and the active layer, thereby improving the stability of the TFT device.

In specific implementation, the fourth insulation layer 204 may be exactly the same as the material and preparation process of the second insulation layer 202 to ensure process consistency. In other embodiments, it may also be different within the range of the first type of insulation material provided in the above embodiments.

In some embodiments, as shown in FIG. 7, the display panel may also include a fifth insulation layer 205. The fifth insulation layer 205 may be located between the first insulation layer 201 and the first gate metal layer MG1; and the fifth insulation layer 205 may be made of the second type of insulation material.

To reduce the manufacturing cost while ensuring the thickness of the insulation layer, the above embodiment of the present disclosure may dispose the fifth insulation layer 205 made of the second type of insulation material on the upper layer of the first insulation layer 201 to reduce the amount of the first type of insulation material. At the same time, between the first insulation layer 201 and the first gate metal layer MG1, the insulation performance and hydrogen barrier capability of the stacked insulation structure composed of the first insulation layer 201 and the fifth insulation layer 205 may be guaranteed, avoiding the threshold voltage shift and the reduction of the on-current of the TFT device caused by the contact between the free hydrogen atoms and the active layer, thereby improving the stability of the TFT device.

In one embodiment, the fifth insulation layer 205 may be made of the same material and by a same preparation process as the fourth insulation layer 204 and the second insulation layer 202 to ensure the process consistency. In other embodiments, it may also be different within the range of the first type of insulation material provided in the above embodiment.

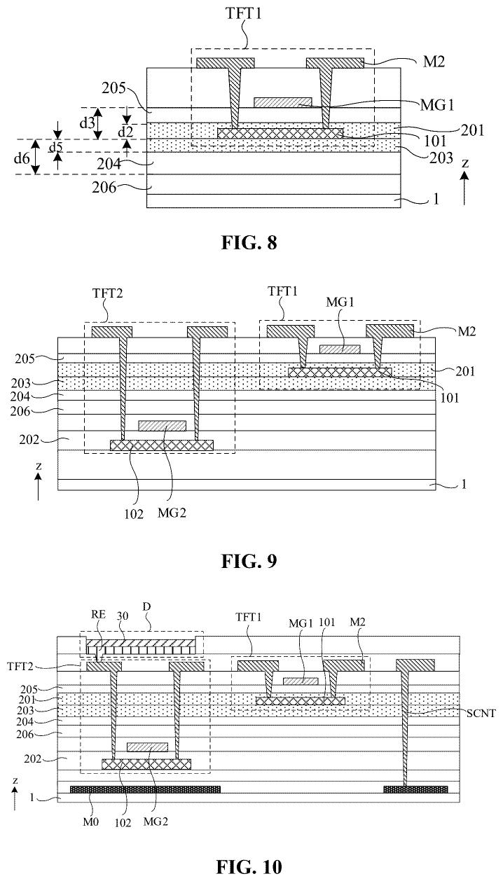

In one embodiment, as shown in FIG. 8, the display panel may include the above-mentioned first active layer 101, the first gate metal layer MG1, the first insulation layer 201, the third insulation layer 203, the fourth insulation layer 204, the fifth insulation layer 205 and the sixth insulation layer 206. Those skilled in the art may also obtain more embodiment combinations based on the above contents of the present disclosure, which are all within the protection scope of the present disclosure.

In one embodiment, as shown in FIG. 9, each insulation layer in the display panel may be deposited as a whole layer. The display panel may also include the third insulation layer 203, the fourth insulation layer 204, the fifth insulation layer 205 and/or the sixth insulation layer 206 at the corresponding position of the second transistor TFT2.

Specifically, in the embodiments shown in FIG. 5 and FIG. 6, when only the first insulation layer 201 is included between the first active layer 101 and the first gate metal layer MG1, the thickness d1 of the first insulation layer 201 may be in a range of approximately 100 nm and 400 nm in the direction z perpendicular to the plane of the substrate 1.

The insulation layers in the display panel need to have a certain thickness to ensure that the insulation layer has a certain breakdown voltage, control leakage current, reduce the influence of interface states and constant charges, and improve the mechanical strength and reliability of the device. When the first insulation layer 201 is generated using the above-mentioned first type of insulation material, a thickness of 100 nm may ensure its basic insulation, structural reliability and hydrogen resistance. As the thickness increases, the performance of the insulation layer is correspondingly improved. To reduce the overall thickness of the display panel and save production costs, the thickness of the first insulation layer 201 may not be greater than 400 nm.

Specifically, in the embodiments shown in FIG. 7 and FIG. 8, when the first active layer 101 and the first gate metal layer MG1 include a stacked insulation structure consisting of the first insulation layer 201 and the fifth insulation layer 205, the thickness d2 of the first insulation layer 201 may be in a range of approximately 20 nm and 200 nm in the direction z perpendicular to the plane of the substrate 1.

To save production costs, when the stacked insulation structure consisting of the first insulation layer 201 and the fifth insulation layer 205 is used, the amount of the first type of insulation material may be reduced, that is, compared with the embodiments shown in FIGS. 5-6, the thickness of the first insulation layer 201 generated by the first type of insulation material in the embodiments shown in FIGS. 7-8 may be thinned. When the thickness is 20 nm, the first insulation layer 201 may have the basic hydrogen blocking ability and may effectively prevent free hydrogen atoms from contacting the active layer; at the same time, to reduce the overall thickness of the display panel and save production costs, in the embodiments shown in FIGS. 7-8, the thickness of the first insulation layer 201 may not be greater than 200 nm.

In the embodiments shown in FIGS. 7-8, in the direction z perpendicular to the plane of the substrate 1, the total thickness d3 of the first insulation layer 201 and the fifth insulation layer 205 may be in a range of approximately 200 nm and 500 nm.

When the stacked insulation structure composed of the above-mentioned first insulation layer 201 and the fifth insulation layer 205 is used, the total thickness of 200 nm may ensure the basic insulation, structural reliability and hydrogen blocking ability of the stacked insulation structure. As the thickness increases, the performance of the insulation layer may be correspondingly improved. At the same time, to reduce the overall thickness of the display panel, the total thickness of the stacked insulation structure may not be greater than 500 nm.

In the embodiment shown in FIG. 5, when only the third insulation layer 203 is included between the first active layer 101 and the sixth insulation layer 206, the thickness d4 of the third insulation layer 203 may be in a range of approximately 100 nm and 400 nm in the direction z perpendicular to the plane of the substrate 1.

The insulation layers in the display panel may need to have a certain thickness to ensure the insulation layer to have a certain breakdown voltage, control leakage current, reduce the influence of interface states and fixed charges, and improve the mechanical strength and reliability of the device. When the third insulation layer 203 is generated using the above-mentioned first type of insulation material, a thickness of 100 nm may ensure its basic insulation, structural reliability and hydrogen barrier ability. As the thickness increases, the performance of the insulation layer may be correspondingly improved. To reduce the overall thickness of the display panel and the production cost, the thickness of the third insulation layer 203 may not exceed 400 nm.

In some embodiments, as shown in FIG. 6 and FIG. 8, the display panel may include the sixth insulation layer 206 and the fourth insulation layer 204. The fourth insulation layer 204 and the third insulation layer 203 may be located between the first active layer 101 and the sixth insulation layer 206. In the direction z perpendicular to the plane of the substrate 1, the thickness d5 of the third insulation layer 203 may be in a range of approximately 20 nm and 200 nm.

To reduce the manufacturing cost, when the stacked insulation structure composed of the fourth insulation layer 204 and the third insulation layer 203 is used, the amount of the first type of insulation material may be reduced, that is, compared with the embodiment shown in FIG. 5, the thickness of the third insulation layer 203 generated by the first type of insulation material in the embodiments shown in FIG. 6 and FIG. 8 may be reduced. When the thickness is 20 nm, the third insulation layer 203 may have the basic hydrogen blocking ability and may effectively prevent free hydrogen atoms from contacting the active layer; at the same time, to reduce the overall thickness of the display panel and reduce production costs, in the embodiments shown in FIG. 6 and FIG. 8, the thickness of the third insulation layer 203 may not be greater than 200 nm.

In the embodiments shown in FIG. 6 and FIG. 8, in the direction perpendicular to the substrate plane, the sum of the thicknesses d6 of the third insulation layer 203 and the fourth insulation layer 204 may be in a range of approximately 200 nm and 500 nm.

When the stacked insulation structure composed of the fourth insulation layer 204 and the third insulation layer 203 is used, the total thickness of 200 nm may ensure the basic insulation, structural reliability and hydrogen blocking ability of the stacked insulation structure. As the thickness increases, the performance of the insulation layer may be correspondingly improved. At the same time, to reduce the overall thickness of the display panel, the total thickness of the stacked insulation structure may not exceed 500 nm.

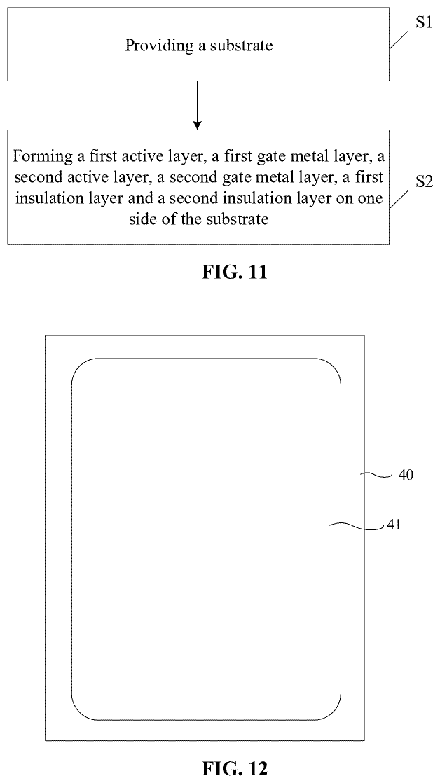

In one embodiment, as shown in FIG. 10, the display panel provided by the embodiment of the present disclosure may also include a protective metal layer M0. The protective metal layer M0 may be at least partially located between the second active layer 102 and the substrate 1, that is, located at the bottom of the second transistor TFT, thereby shielding static electricity coming from the back of the display panel and protecting the TFT from static electricity.

In one embodiment, as shown in FIG. 10, because the IGZO transistor (i.e., the first transistor TFT1) may be farther away from the substrate 1 than the LTPS transistor (i.e., the second transistor TFT2), the protective metal layer M0 may not be provided at the position corresponding to the IGZO transistor.

Specifically, for better electrostatic protection effect, as shown in FIG. 10, the protective metal layer M0 may also be connected to the constant potential signal line through the metal via SCNT, and may receive the substrate voltage (which may be equal to the power supply voltage) provided by the constant potential signal line to avoid the bottom electric field effect caused by the accumulation of electrostatic charge and to enhance the antistatic ability of the protective metal layer M0.

In one embodiment, as shown in FIG. 10, the display panel provided by the embodiment of the present disclosure may also include a light-emitting element D composed of an anode metal RE and an organic light-emitting layer 30. The anode metal layer RE may be electrically connected to the TFT device in the pixel driving circuit, such that the organic light-emitting layer 30 may be lighted.

The present disclosure also provides a method for fabricating a display panel. FIG. 11 illustrates a flowchart of an exemplary fabrication process of a display panel according to various embodiments of the present disclosure.

As shown in FIG. 11, the fabrication process may include: S1: providing a substrate; and S2: forming a first active layer, a first gate metal layer, a second active layer, a second gate metal layer, a first insulation layer and a second insulation layer on one side of the substrate. The first insulation layer may be located between the first active layer and the first gate metal layer, and the second insulation layer may be located between the second active layer and the second gate metal layer. An exemplary prepared display panel may be referred to FIG. 2. The first insulation layer may be made of a first type of insulation material; and the second insulation layer may be made of a second type of insulation material. The oxygen content of the first type of insulation material may be less than the oxygen content of the second type of insulation material. In one embodiment, each film layer in the above embodiment may be deposited in sequence according to its position in the cross-sectional structure of the display panel.

The fabrication method provided in the embodiments of the present disclosure may provide an insulation layer with less oxygen content and a denser structure between the active layer and the gate metal layer of the TFT, such that the insulation layer may have both insulation properties and hydrogen blocking capabilities, avoiding the problem of threshold voltage offset and on-current reduction of the TFT device caused by the contact between free hydrogen atoms and the active layer, thereby improving the stability of the TFT device and also avoiding excessive etching of the TFT.

In some embodiments, the process of forming the first insulation layer in S2 above may include forming a first insulation layer made of a first type of insulation material by an atomic layer deposition method or a high density plasma chemical vapor deposition method.

The atomic layer deposition method may deposit only one atomic layer or molecular layer in each cycle by layer-by-layer depositions. This self-limiting reaction mechanism may ensure that each deposition only reacts on the exposed surface, thereby avoiding unnecessary oxidation reactions. In addition, the atomic layer deposition method is usually carried out in a high vacuum or low-pressure environment. In each deposition, the precursor gas may be introduced in excess to ensure that the surface is completely saturated; in the process of introducing and removing the precursor gas, an inert gas (such as nitrogen or argon) is usually used for purging, thereby reducing the introduction of impurities such as oxygen. Furthermore, the insulation material and the insulation layer formed by the atomic layer deposition method may have a low oxygen content, which may provide a denser insulation layer, such that the insulation layer may have both insulation properties and hydrogen barrier capabilities, avoiding the threshold voltage shift and on-current reduction of the TFT device caused by the contact between free hydrogen atoms and the active layer, thereby improving the stability of the TFT device.

Active particles in the high density plasma process may efficiently promote chemical reactions and reduce unnecessary oxidation reactions. The high density plasma chemical vapor deposition method may be carried out in a high vacuum or low-pressure environment, which may remove oxygen and other impurity gases in the reaction chamber. When introducing the precursor gas, an inert gas (such as nitrogen or argon) may be usually used for purging, thereby reducing the introduction of impurities such as oxygen. Furthermore, the insulation material and insulation layer formed by the high-density plasma chemical vapor deposition may have a low oxygen content, which may provide a denser insulation layer, such that the insulation layer may have both insulation properties and hydrogen barrier capabilities, avoiding the threshold voltage shift and conduction current reduction of the TFT device caused by the contact between free hydrogen atoms and the active layer, thereby improving the stability of the TFT device.

When the first insulation layer formed by the atomic layer deposition process or the high density plasma chemical vapor deposition process, the first type of insulation material may include silicon oxide or silicon nitride to reduce material costs, while also ensuring that the first insulation layer may have a low oxygen content.

In one embodiment, the process of forming the second insulation layer in S2 may include forming a second insulation layer composed of a second type of insulation material by the conventional chemical vapor deposition process. The second type of insulation material may be silicon oxide or silicon nitride. In one embodiment, the second type of insulation material includes silicon oxide.

In some embodiments, the process of forming the first insulation layer in S2 may include forming a first insulation layer composed of aluminum oxide or hafnium oxide.

Compared with silicon oxide, aluminum oxide and hafnium oxide may have a lower oxygen atom density (in aluminum oxide, each aluminum atom is combined with three oxygen atoms, while in silicon oxide, each silicon atom is combined with two oxygen atoms; although the chemical formulas of hafnium oxide and silicon oxide both indicate that each metal atom is combined with two oxygen atoms, the atomic weight of hafnium atoms (178.49) is much greater than that of silicon atoms (28.09)). Therefore, on the basis of the same thickness, the oxygen content of the insulation layer composed of aluminum oxide or hafnium oxide may be lower than that of the insulation layer composed of silicon oxide, which may provide a denser insulation layer, such that the insulation layer may have both insulation properties and hydrogen barrier capabilities, avoiding the problem of threshold voltage shift and reduced on-current of TFT devices caused by contact between free hydrogen atoms and the active layer, thereby improving the stability of TFT devices.

In one embodiment, when the first type of insulation material includes aluminum oxide or hafnium oxide, the corresponding first insulation layer fabrication method may adopt the above-mentioned atomic layer deposition method or high density plasma chemical vapor deposition method, or may adopt a conventional chemical vapor deposition method or other related technologies to for the insulation layer.

In some embodiments, the fabrication method may further include forming a third insulation layer 203 on the side of the first active layer 101 away from the first gate metal layer MG1, as shown in FIG. 5. The third insulation layer 203 may also be composed of the first type of insulation material. The third insulation layer 203 and the first insulation layer 201 may together wrap the first active layer 101, further preventing the free hydrogen atoms in the insulation layer from contacting the first active layer 101, thereby improving the stability of the TFT device.

In some embodiments, the fabrication method may further include forming a fourth insulation layer 204 on the side of the third insulation layer 203 away from the first active layer 101, as shown in FIG. 6. The fourth insulation layer 204 may be made of the second type of insulation material.

In the above embodiment of the present disclosure, a fourth insulation layer 204 made of the second type of insulation material may be disposed under the third insulation layer 203 to reduce the amount of the first type of insulation material; at the same time, the third insulation layer 203 may be located between the fourth insulation layer 204 and the first active layer 101, which may ensure the insulation performance and hydrogen barrier capability of the stacked insulation structure composed of the third insulation layer 203 and the fourth insulation layer 204, and may avoid the problem of threshold voltage shift and conduction current reduction of the TFT device caused by the contact between free hydrogen atoms and the active layer, thereby improving the stability of the TFT device.

In some embodiments, the fabrication method may also include forming a fifth insulation layer 205 between the first insulation layer 201 and the first gate metal layer MG1, as shown in FIG. 7. The fifth insulation layer 205 may be composed of the second type of insulation material.

To reduce the manufacturing cost while ensuring the thickness of the insulation layer, the above embodiments of the present disclosure may dispose a fifth insulation layer 205 made of the second type of insulation material on the upper layer of the first insulation layer 201 to reduce the amount of the first type of insulation material. At the same time, the fifth insulation layer 205 may be disposed between the first insulation layer 201 and the first gate metal layer MG1, the insulation performance and hydrogen barrier capability of the stacked insulating structure composed of the first insulation layer 201 and the fifth insulation layer 205 may be guaranteed, avoiding the threshold voltage shift and the reduction of the on-current of the TFT device caused by the contact between the free hydrogen atoms and the active layer, thereby improving the stability of the TFT device.

It should be noted that the method of the embodiment of the present application may be executed by a single device, such as a computer or a server. The method may also be applied to a distributed scenario and completed by multiple devices cooperating with each other. In the case of such a distributed scenario, one of the multiple devices may only execute one or more steps in the methods of the embodiments of the present application, and the multiple devices may interact with each other to complete the above method.

It should be noted that some embodiments of the present disclosure are described above. Other embodiments are within the scope of the attached claims. In some cases, the actions or steps described in the claims may be performed in different orders than in the above embodiments and still achieve the desired results. In addition, the process depicted in the drawings does not necessarily require the specific order or continuous order shown to achieve the desired results. In some embodiments, multitasking and parallel processing may also be possible or may be advantageous.

The method of the above embodiment may be used to form the corresponding display panel in any of the above embodiments, and has the beneficial effects of the corresponding embodiment, which will not be repeated here.

Further, the present disclosure provides a display device. FIG. 12 illustrates an exemplary display device according to various embodiments of the present disclosure. As shown in FIG. 12, the display device 40 may include a display panel 41. The display panel 41 may include the display panel described in any of the above embodiments.

The display panel of the display device provided by the embodiment of the present disclosure may provide an insulation layer with less oxygen content and more compactness between the active layer and the gate metal layer of the TFT, such that the insulation layer may have both insulating properties and hydrogen blocking capabilities, avoiding the problem of threshold voltage shift and on-current reduction of the TFT device caused by the contact between the free hydrogen atoms and the active layer, thereby improving the stability of the TFT device and avoiding excessive etching of the TFT.

Specifically, the display device may be “3C” electronic products including computer and its peripherals, communication and consumer electronics, such as a smart phone, a laptop, a tablet computer, a smart wearable device, a home appliance, a gaming device, etc. Further, the display device may also be applied to other types of electronic devices such as automotive electronics, etc.

The device of the above embodiments may include the corresponding display panel in any of the above embodiments, and may have the beneficial effects of the corresponding embodiments, which will not be repeated here.

The display panel provided by the present disclosure may have the following advantages. The display panel provided by the present disclosure may provide an insulation layer with less oxygen content and more density between the active layer and the gate metal layer of the TFT, such that the insulation layer may have both insulation properties and hydrogen barrier capabilities, thereby avoiding the problems of threshold voltage shift and reduced on-current of the TFT device caused by contact between free hydrogen atoms and the active layer, thereby improving the stability of the TFT device.

It should be noted that, in this disclosure, relational terms such as “first” and “second” are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, the elements defined by the sentence “including one . . . ” do not exclude the existence of other identical elements in the process, method, article or device including the above elements.

The above are only specific embodiments of the present disclosure, which enable those skilled in the art to understand or implement the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments described above, but will conform to the widest scope consistent with the principles and novel features disclosed herein.

What is claimed is:

1. A display panel, comprising:
a substrate; and
a first active layer, a first gate metal layer, a second active layer, a second gate metal layer, a first insulation layer and a second insulation layer disposed on one side of the substrate,
wherein:
the first insulation layer is located between the first active layer and the first gate metal layer;
the second insulation layer is located between the second active layer and the second gate metal layer;
the first insulation layer is made of a first type of insulation material;
the second insulation layer is made of a second type of insulation material; and
an oxygen content of the first type of insulation material is less than an oxygen content of the second type of insulation material.

2. The display panel according to claim 1, wherein:
the first active layer includes an oxide semiconductor layer.

3. The display panel according to claim 1, wherein:
the first type of insulation material is formed by an atomic layer deposition process or a high density plasma chemical vapor deposition process.

4. The display panel according to claim 3, wherein:
the first type of insulation material includes silicon oxide or silicon nitride.

5. The display panel according to claim 1, wherein:
the first type of insulation material includes aluminum oxide or hafnium Oxide.

6. The display panel according to claim 1, further comprising:
a third insulation layer located on a side of the first active layer away from the first gate metal layer and made of the first type of insulation material.

7. The display panel according to claim 6, further comprising:
a fourth insulation layer located on a side of the third insulation layer away from the first active layer and made of the second type of insulation material.

8. The display panel according to claim 1, further comprising:
a fifth insulation layer located between the first insulation layer and the first gate metal layer and made of the second type of insulation material.

9. The display panel according to claim 1, wherein:
the second type of insulation material includes silicon oxide.

10. The display panel according to claim 1, wherein:
only the first insulation layer is included between the first active layer and the first gate metal layer; and
in a direction perpendicular to a plane of the substrate, a thickness of the first insulation layer is in a range of approximately 100 nm and 400 nm.

11. The display panel according to claim 8, wherein:
in a direction perpendicular to a plane of the substrate, a thickness of the first insulation layer is in a range of approximately 20 nm and 200 nm.

12. The display panel according to claim 11, wherein:
in the direction perpendicular to the plane of the substrate, a total thickness of the first insulation layer and the fifth insulation layer is in a range of approximately 200 nm and 500 nm.

13. The display panel according to claim 6, further comprising:
a sixth insulation layer located a side of the third insulation layer away from the first active layer and made of silicon nitride,
wherein:
only the third insulation layer is included between the first active layer and the sixth insulation layer; and
in a direction perpendicular to a plane of the substrate, a thickness of the third insulation layer is in a range of approximately 100 nm and 400 nm.

14. The display panel according to claim 7, wherein:
in a direction perpendicular to a plane of the substrate, a thickness of the third insulation layer is in a range of approximately 20 nm and 400 nm.

15. The display panel according to claim 14, wherein:
in the direction perpendicular to the plane of the substrate, a total thickness of the third insulation layer and the fourth insulation layer is in a range of approximately 200 nm and 500 nm.

16. A method for fabricating a display panel, comprising:
providing a substrate; and
forming a first active layer, a first gate metal layer, a second active layer, a second gate metal layer, a first insulation layer and a second insulation layer on one side of the substrate,
wherein:
the first insulation layer is located between the first active layer and the first gate metal layer;
the second insulation layer is located between the second active layer and the second gate metal layer;
the first insulation layer is made of a first type of insulation material;
the second insulation layer is made of a second type of insulation material; and
an oxygen content of the first type of insulation material is less than an oxygen content of the second type of insulation material.

17. The method according to claim 16, wherein forming the first insulation layer comprises:
forming the first insulation layer made of the first type of insulation material by an atomic layer deposition process or a high density plasma chemical vapor deposition process.

18. A display device, comprising:
a display panel, including:
a substrate; and
a first active layer, a first gate metal layer, a second active layer, a second gate metal layer, a first insulation layer and a second insulation layer disposed on one side of the substrate,
wherein:
the first insulation layer is located between the first active layer and the first gate metal layer;
the second insulation layer is located between the second active layer and the second gate metal layer;
the first insulation layer is made of a first type of insulation material;
the second insulation layer is made of a second type of insulation material; and
an oxygen content of the first type of insulation material is less than an oxygen content of the second type of insulation material.
